(19) United States
(12) Patent Application Publication
(10) Pub. No.: US 2026/0339214 A1
(43) Pub. Date: Oct. 29, 2026

(54) STEP SUBSTRATE COATING COMPOSITION

(71) Applicant: NISSAN CHEMICAL CORPORATION, Tokyo (JP)

(72) Inventors: Yuki Mitsutake, Toyama-shi (JP); Hayato Hattori, Toyama-shi (JP); Tomotada Hirohara, Toyama-shi (JP)

(73) Assignee: NISSAN CHEMICAL CORPORATION, Tokyo (JP)

(21) Appl. No.: 19/721,536

(22) Filed: Jun. 26, 2026

Related U.S. Application Data
(62) Division of application No. 18/025,780, filed on Sep. 2, 2021.

(30) Foreign Application Priority Data
Sep. 16, 2020 (JP) 2020-155549

(51) Int. Cl. G03F 7/11; C08F 138/00; H10P 50/00; H10P 50/28

(52) U.S. Cl. CPC G03F 7/11; C08F 138/00; H10P 50/287; H10P 50/73

(57) ABSTRACT

A step substrate coating composition for efficiently forming a coating that is capable of filling and flattening a pattern. A step substrate coating composition comprising a compound (A) of a main agent, a crosslinking agent, and a solvent, the compound (A) including a partial structure expressed by formula (A-1) (where the broken line represents bonding with an aromatic ring, the aromatic ring forming a polymer skeleton or a monomer, and n represents an integer of 1-4).

### RELATED APPLICATIONS

The present application is a divisional application of U.S. application Ser. No. 18/025,780 filed Mar. 10, 2023, which in turn is a U.S. national stage application of PCT/JP2021/032321 filed Sep. 2, 2021, claiming priority to Japanese Application 2020-155549 filed Sep. 16, 2020. Each of these prior applications is incorporated herein by reference in its entirety.

### TECHNICAL FIELD

The present invention relates to a stepped substrate coating composition for forming a planarization film on a stepped substrate through curing by heating, and a method for producing a laminated substrate that is planarized by using the stepped substrate coating composition.

### BACKGROUND ART

In recent years, semiconductor integrated circuit devices have been processed with a fine design rule. Exposure light having a shorter wavelength must be used for formation of a finer resist pattern by an optical lithography technique.

However, the depth of focus decreases in association with the use of exposure light having a shorter wavelength, and thus the planarity of a coating film formed on a substrate must be improved. A technique for planarization of the film on the substrate has become important for the production of a semiconductor device having a fine design rule.

Hitherto disclosed planarization film formation methods include, for example, a method for forming a resist underlayer film below a resist film by photocuring.

There has been disclosed a resist underlayer film-forming composition containing a polymer having an epoxy group or an oxetane group in a side chain and a photo-cationic polymerization initiator, or a resist underlayer film-forming composition containing a polymer having a radical polymerizable ethylenically unsaturated bond and a photo-radical polymerization initiator (see Patent Document 1).

There has also been disclosed a resist underlayer film-forming composition containing a silicon-containing compound having a cationic polymerizable reactive group (e.g., an epoxy group or a vinyl group), a photo-cationic polymerization initiator, and a photo-radical polymerization initiator (see Patent Document 2).

There has also been disclosed a semiconductor device production method using a resist underlayer film containing a polymer having a crosslinkable functional group (e.g., a hydroxy group) in a side chain, a crosslinking agent, and a photoacid generator (see Patent Document 3).

There has also been disclosed a photo-crosslinked resist underlayer film incorporating a propargyl group (see Patent Document 4).

### PRIOR ART DOCUMENTS

### Patent Documents

Patent Document 1: WO 2006/115044
Patent Document 2: WO 2007/066597
Patent Document 3: WO 2008/047638
Patent Document 4: WO 2017/154921

### SUMMARY OF THE INVENTION

### Problems to be Solved by the Invention

When a planarization film is formed from a conventional stepped substrate coating composition, the composition should be heated and then irradiated with light. Thus, the conventional composition requires a complicated and cumbersome production process. In the case of photoirradiation, the exposure wavelength and the exposure dose must be controlled in accordance with the type and property of a stepped substrate coating composition to be used. Therefore, such a conventional composition poses a problem in that a planarization film is inefficiently produced by a process including a photoirradiation step requiring a control operation; i.e., high production cost is required for the production of the film.

Thus, an object of the present invention is to provide a stepped substrate coating composition for forming a planarization film on a substrate, wherein the composition can form, through only a heating process, a coating film that fills an open area and a pattern sufficiently.

### Means for Solving the Problems

A first aspect of the present invention is a stepped substrate coating composition comprising a compound (A) serving as a main agent, a crosslinking agent, and a solvent, wherein the compound (A) has a partial structure of the following Formula (A-1):

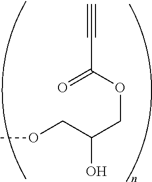

(wherein the broken line is a bond to an aromatic ring; the aromatic ring is an aromatic ring forming a polymer skeleton or a monomer; and n is an integer of 1 to 4).

A second aspect of the present invention is the stepped substrate coating composition according to the first aspect, wherein the aromatic ring is a benzene ring, a naphthalene ring, or an anthracene ring.

A third aspect of the present invention is the stepped substrate coating composition according to the first or second aspect, wherein the polymer containing the aromatic ring is a polymer having a hydroxyaryl novolac structure, and the hydroxyl group of the polymer is substituted with the partial structure of Formula (A-1).

A fourth aspect of the present invention is the stepped substrate coating composition according to the first or second aspect, wherein, in the monomer containing the aromatic ring, the hydroxyl group of the aromatic ring is substituted with the partial structure of Formula (A-1).

A fifth aspect of the present invention is the stepped substrate coating composition according to any one of the first to fourth aspects, wherein the composition further comprises an acid generator.

A sixth aspect of the present invention is the stepped substrate coating composition according to any one of the first to fifth aspects, wherein the composition further comprises a surfactant.

A seventh aspect of the present invention is a coated substrate production method comprising a step (i) of applying the stepped substrate coating composition according to any one of the first to sixth aspects to a stepped substrate; and a step (ii) of heating the composition applied in the step (i).

An eighth aspect of the present invention is the coated substrate production method according to the seventh aspect, wherein the composition is heated at a temperature of 100°C to 500°C in the step (ii).

A ninth aspect of the present invention is the coated substrate production method according to the seventh or eighth aspect, wherein the stepped substrate has an open area (non-patterned area) and a patterned area of DENSE (dense) and ISO (coarse), and the pattern has an aspect ratio of 0.1 to 100.

A tenth aspect of the present invention is the coated substrate production method according to any one of the seventh to ninth aspects, wherein the stepped substrate has an open area (non-patterned area) and a patterned area of DENSE (dense) and ISO (coarse), and the difference in coating level (Bias) between the open area and the patterned area is 1 nm to 50 nm.

An eleventh aspect of the present invention is a semiconductor device production method comprising a step of forming, on a stepped substrate, an underlayer film from the stepped substrate coating composition according to any one of the first to sixth aspects; a step of forming a resist film on the underlayer film; a step of irradiating the resist film with light or electron beams, or heating the resist film during or after irradiation with light or electron beams, and then developing the resist film, to thereby form a resist pattern; a step of etching the underlayer film with the formed resist pattern; and a step of processing the semiconductor substrate with the patterned underlayer film.

A twelfth aspect of the present invention is the semiconductor device production method according to the eleventh aspect, wherein the underlayer film forming step comprises a step (i) of applying the stepped substrate coating composition according to any one of the first to sixth aspects to the stepped substrate; and a step (ii) of heating the composition applied in the step (i).

A thirteenth aspect of the present invention is the semiconductor device production method according to the twelfth aspect, wherein the composition is heated at a temperature of 100°C to 500°C in the step (ii).

A fourteenth aspect of the present invention is the semiconductor device production method according to any one of the eleventh to thirteenth aspects, wherein the stepped substrate has an open area (non-patterned area) and a patterned area of DENSE (dense) and ISO (coarse), and the pattern has an aspect ratio of 0.1 to 100.

A fifteenth aspect of the present invention is the semiconductor device production method according to any one of the eleventh to fourteenth aspects, wherein the stepped substrate has an open area (non-patterned area) and a patterned area of DENSE (dense) and ISO (coarse), and the underlayer film formed from the stepped substrate coating composition has a difference in coating level (Bias) between the open area and the patterned area of 1 nm to 50 nm.

A sixteenth aspect of the present invention is a semiconductor device production method comprising a step of forming, on a stepped substrate, an underlayer film from the stepped substrate coating composition according to any one of the first to sixth aspects; a step of forming a hard mask on the underlayer film; a step of forming a resist film on the hard mask; a step of irradiating the resist film with light or electron beams, or heating the resist film during or after irradiation with light or electron beams, and then developing the resist film, to thereby form a resist pattern; a step of etching the hard mask with the formed resist pattern; a step of etching the underlayer film with the patterned hard mask; and a step of processing the semiconductor substrate with the patterned underlayer film.

A seventeenth aspect of the present invention is the semiconductor device production method according to the sixteenth aspect, wherein the underlayer film forming step comprises a step (i) of applying the stepped substrate coating composition according to any one of the first to sixth aspects to the stepped substrate; and a step (ii) of heating the composition applied in the step (i).

An eighteenth aspect of the present invention is the semiconductor device production method according to the seventeenth aspect, wherein the composition is heated at a temperature of 100°C to 500°C in the step (ii).

A nineteenth aspect of the present invention is the semiconductor device production method according to the seventeenth or eighteenth aspect, wherein the stepped substrate has an open area (non-patterned area) and a patterned area of DENSE (dense) and ISO (coarse), and the pattern has an aspect ratio of 0.1 to 100.

A twentieth aspect of the present invention is the semiconductor device production method according to any one of the seventeenth to nineteenth aspects, wherein the stepped substrate has an open area (non-patterned area) and a patterned area of DENSE (dense) and ISO (coarse), and the underlayer film formed from the stepped substrate coating composition has a difference in coating level (Bias) between the open area and the patterned area of 1 nm to 50 nm.

### Effects of the Invention

The stepped substrate coating composition of the present invention can be cured by only heating. Thus, a resist underlayer film can be produced by a simple process, and the resist underlayer film and a coated substrate can be produced at high efficiency. The stepped substrate coating composition of the present invention can form a flat film on a stepped substrate regardless of an open area (non-patterned area) or a patterned area of DENSE (dense) and ISO (coarse) on the stepped substrate.

Thus, the stepped substrate coating composition of the present invention can provide an excellent planarization film that achieves sufficient filling of an open area and a patterned area, as well as good planarity after filling of these areas.

### MODES FOR CARRYING OUT THE INVENTION

### [Main Agent]

The present invention is directed to a stepped substrate coating composition containing a compound (A) serving as a main agent, a crosslinking agent, and a solvent, wherein the compound (A) has a partial structure of the following Formula (A-1).

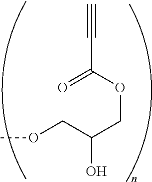

In Formula (A-1), n is an integer of 1 to 4; the broken line is a bond to an aromatic ring; and the aromatic ring is an aromatic ring forming a polymer skeleton or a monomer.

The aforementioned aromatic ring may be a benzene ring, a naphthalene ring, or an anthracene ring.

The polymer containing the aromatic ring may be a polymer having a hydroxyaryl novolac structure, wherein the hydroxyl group of the polymer may be substituted with the partial structure of Formula (A-1). The aryl group may be an aromatic group derived from benzene or naphthalene.

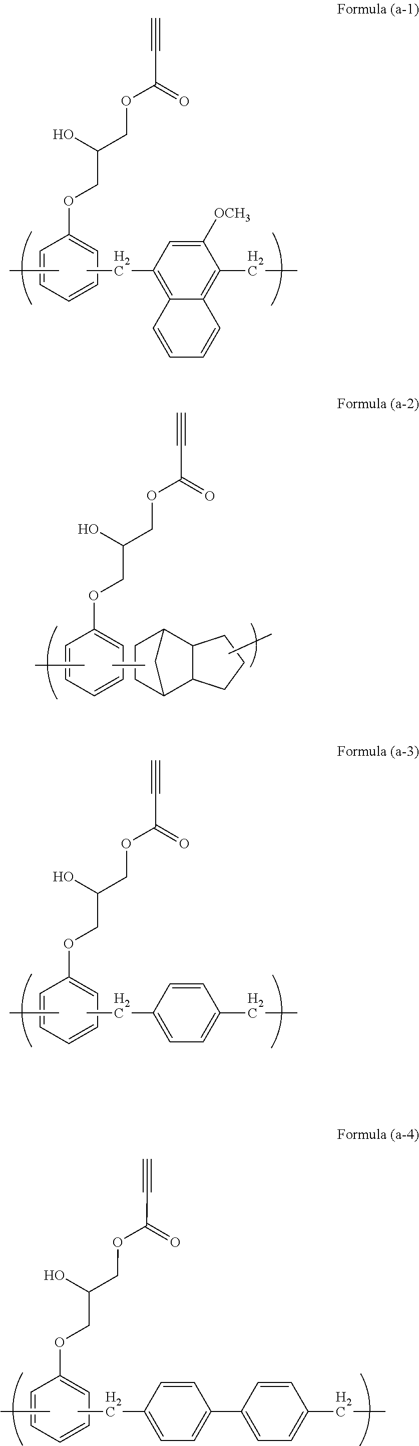

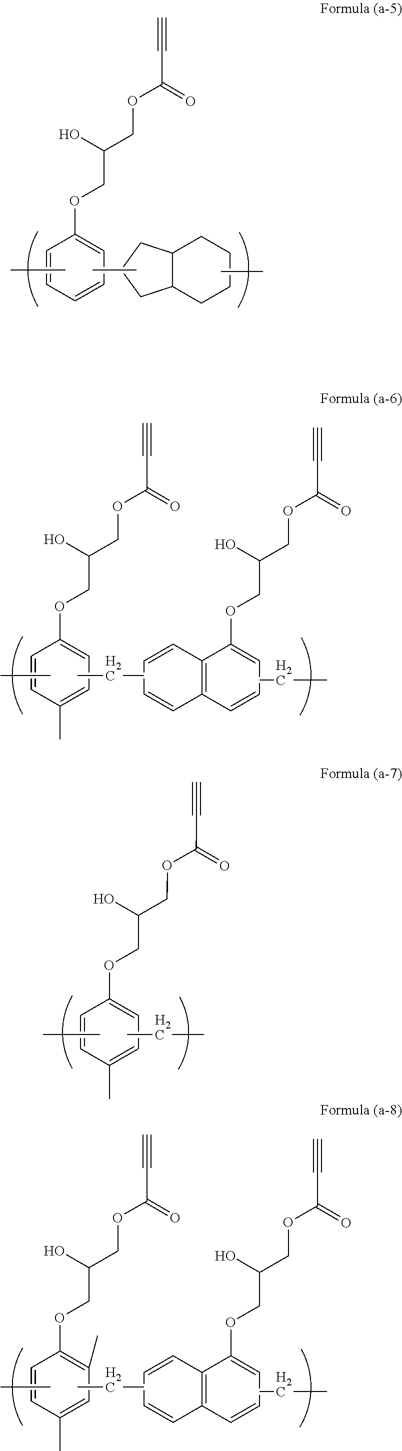

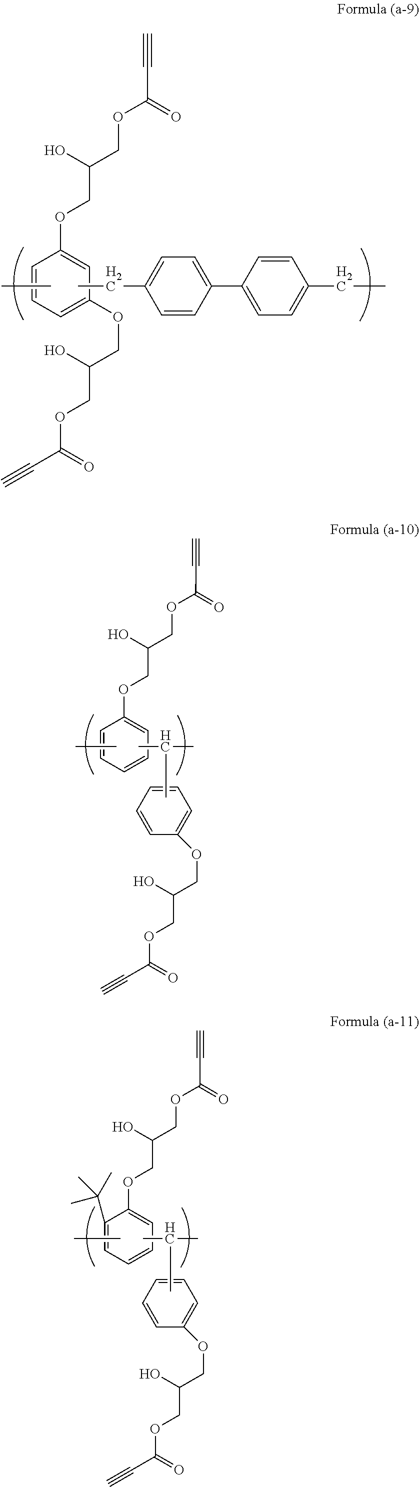

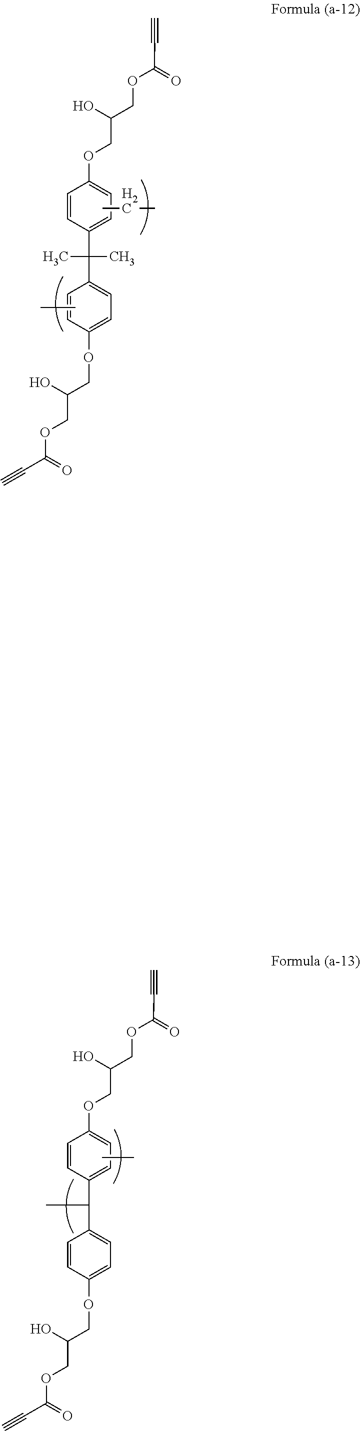

No limitation is imposed on the production method for each of the polymers of Formulae (a-1) to (a-13). Each of these polymers is synthesized according to any known method by, for example, condensation reaction between the epoxy group of a precursor polymer and propiolic acid.

The aforementioned polymer has a weight average molecular weight of 600 to 1,000,000, or 600 to 200,000, or 1,500 to 15,000.

In the present invention, the monomer containing the aromatic ring may be a monomer wherein the glycidyl ether group of the aromatic ring is substituted with the partial structure of Formula (A-1).

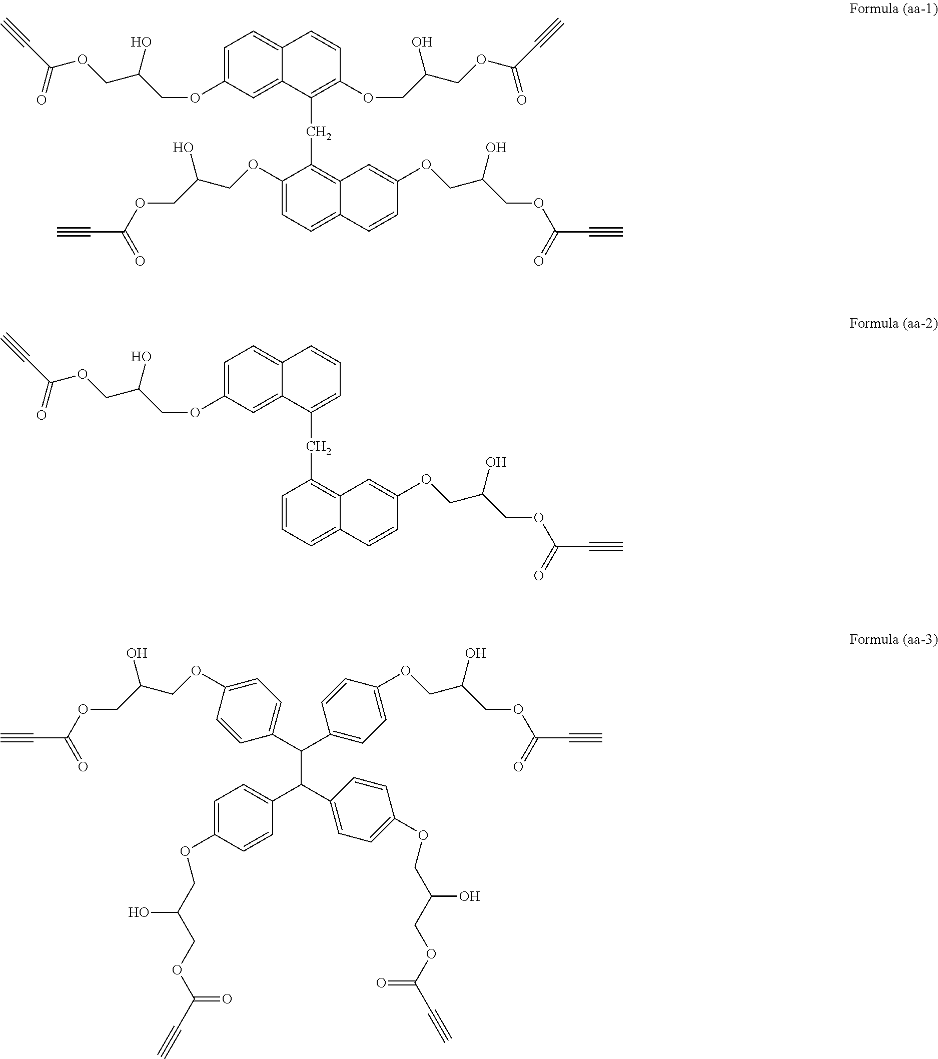

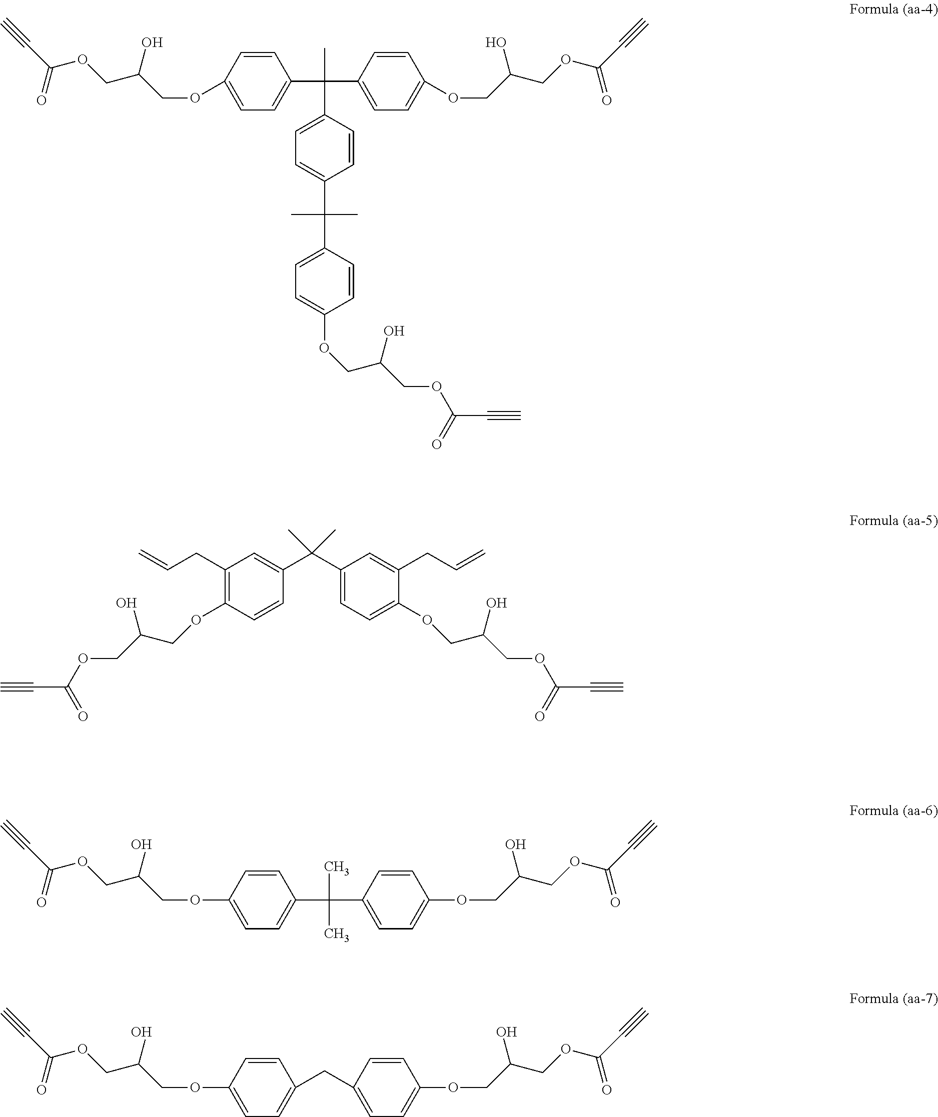

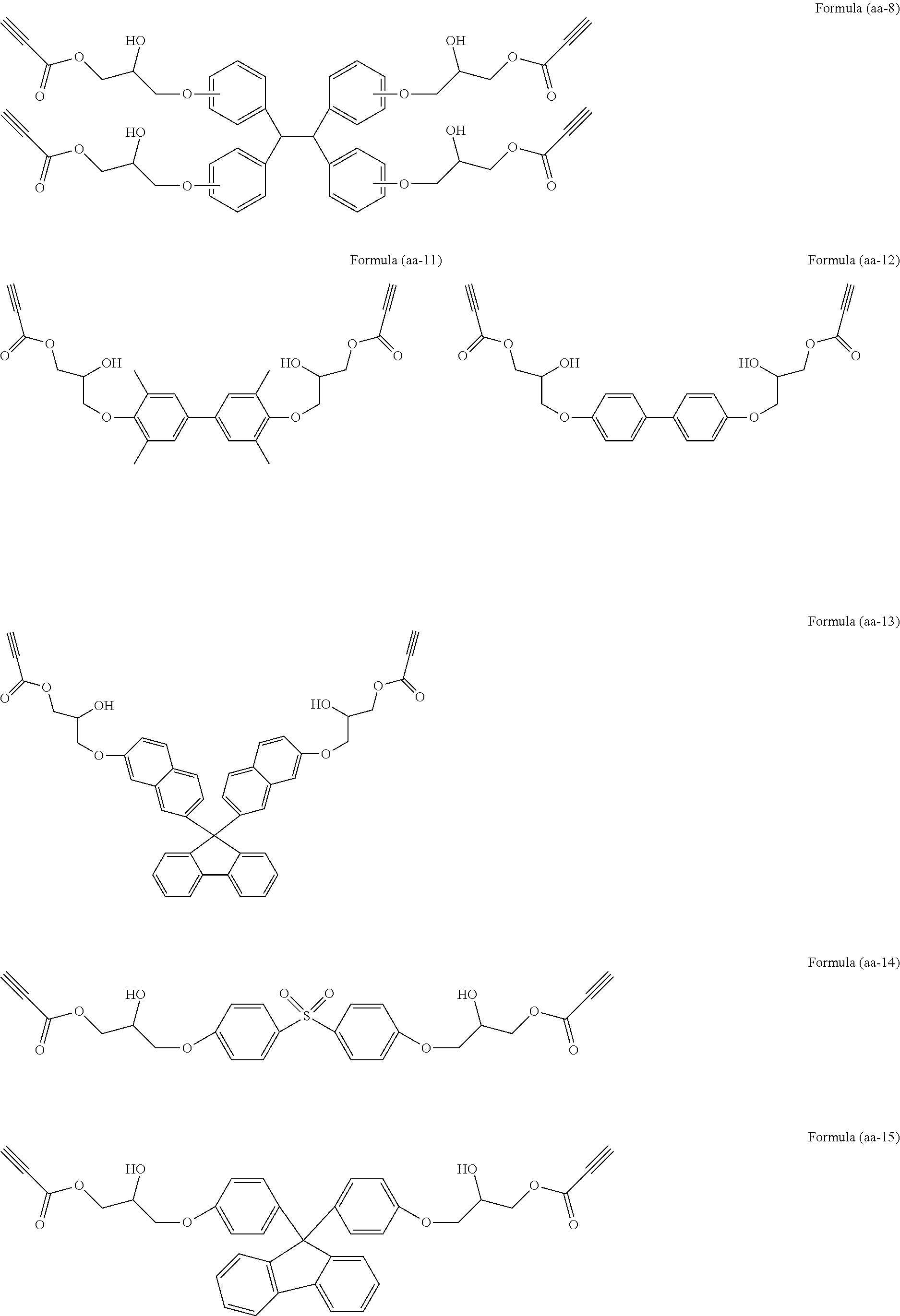

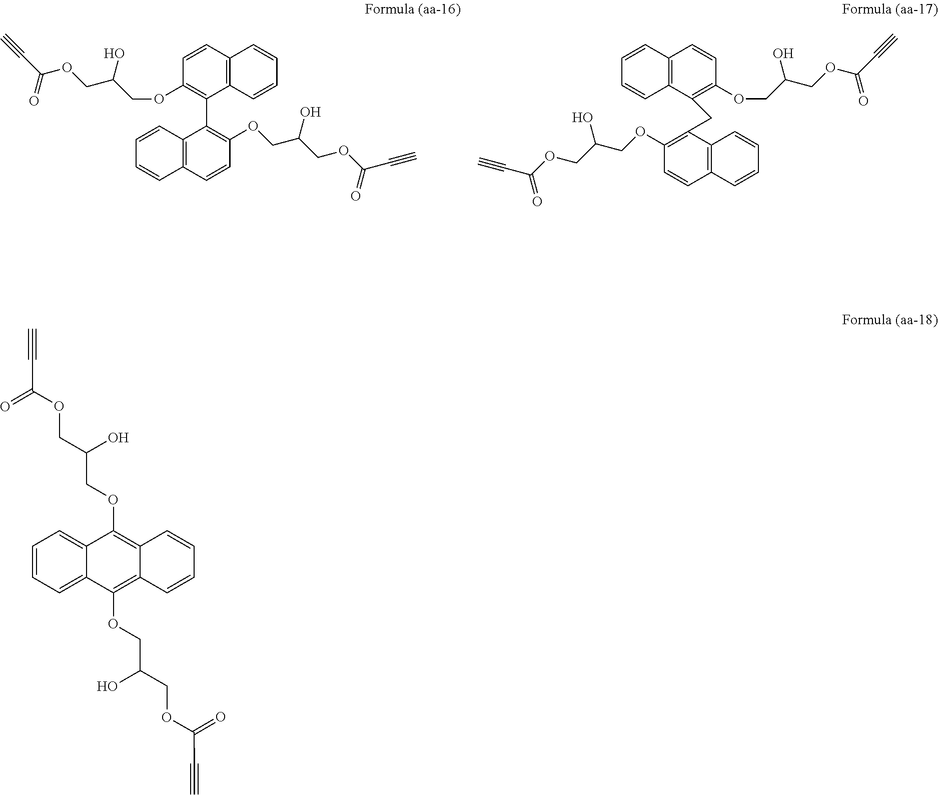 [SMILES: C#CC(=O)OCC(O)COc1ccc2ccccc2c1-c1c(OCC(O)COC(=O)C#C)ccc2ccccc12 ; C#CC(=O)OCC(O)COc1ccc2ccccc2c1Cc1c(OCC(O)COC(=O)C#C)ccc2ccccc12 ; C#CC(=O)OCC(O)COc1c2ccccc2c(OCC(O)COC(=O)C#C)c2ccccc12]

Each of the monomer compounds of Formulae (aa-1) to (aa-8) and (aa-11) to (aa-18) is synthesized by substitution of the epoxy group of a precursor monomer through condensation with propiolic acid.

The aforementioned monomer containing the aromatic ring may have a molecular weight of 200 to 10,000, or 200 to 2,000, or 200 to 1,000.

The aforementioned polymer or monomer containing the aromatic ring may be mixed and reacted with any other aromatic carboxylic acid during reaction with propiolic acid.

Examples of the aromatic carboxylic acid include benzoic acid, naphthalenecarboxylic acid, anthracenecarboxylic acid, and pyrenecarboxylic acid. In such a carboxylic acid, the benzene ring may have thereon one or more substituents, such as a hydroxyl group, an aldehyde group, a methoxymethyl group, an amino group, a methylol group, an allyl group, an ethynyl group, and a propargyl group.

The ratio of the aromatic carboxylic acid to propiolic acid is as follows; i.e., the amount of the aromatic carboxylic acid is about 0.1 to 50 mol, preferably about 0.1 to 10 mol, more preferably 0.1 to 2 mol, relative to 1 mol of propiolic acid.

Examples of the polymer or monomer prepared by mixing and reaction between propiolic acid and an aromatic carboxylic acid include those described below.

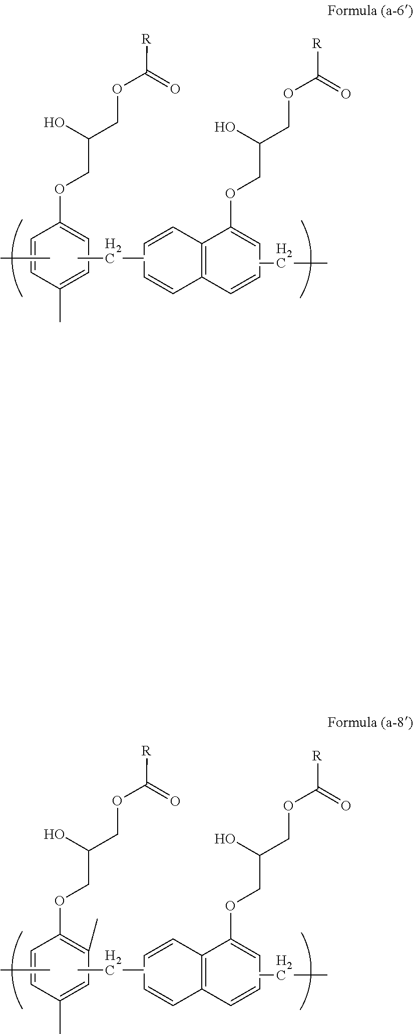

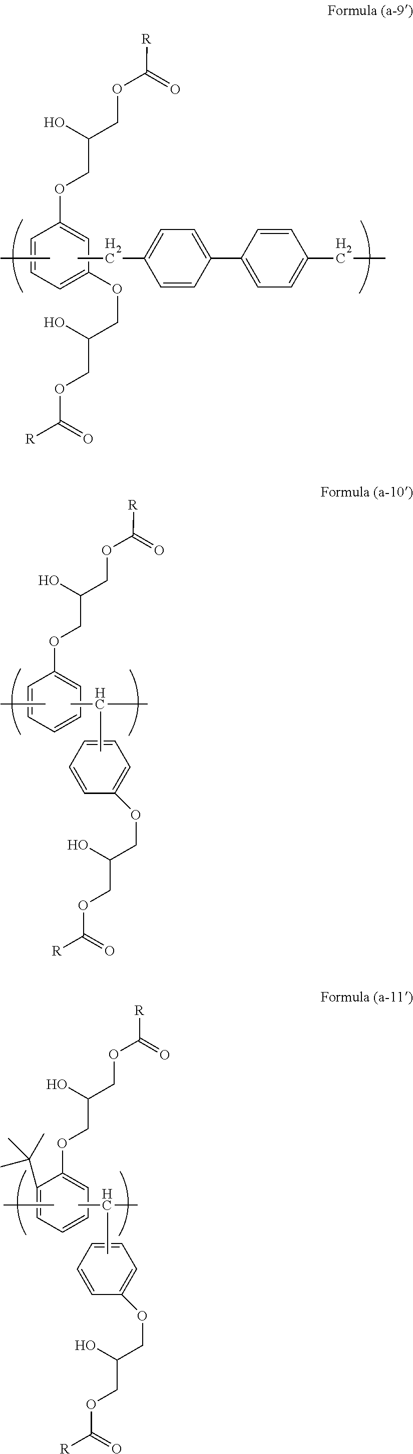

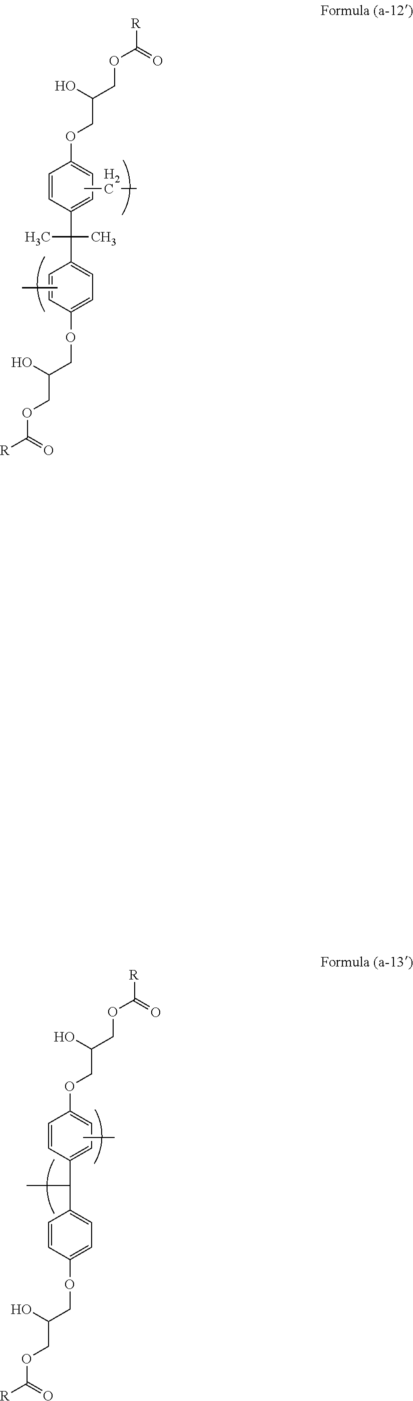

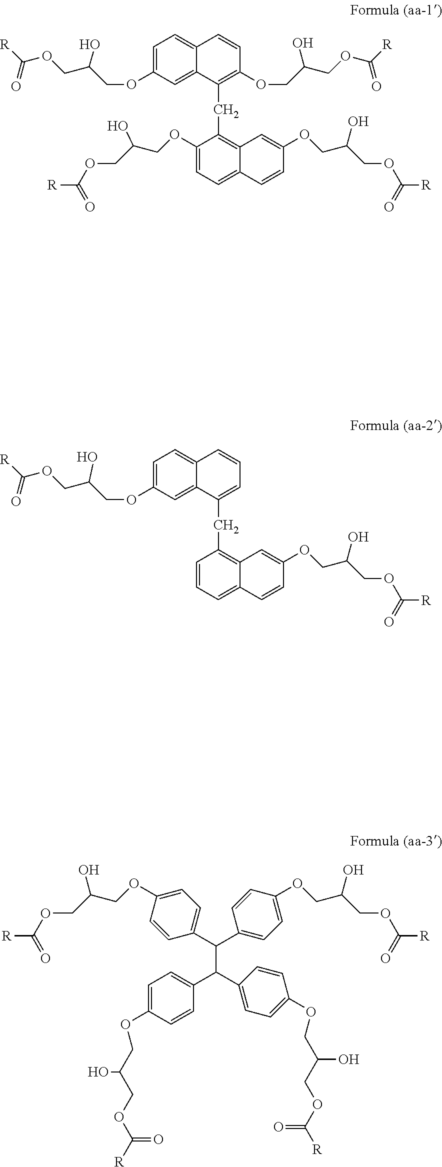

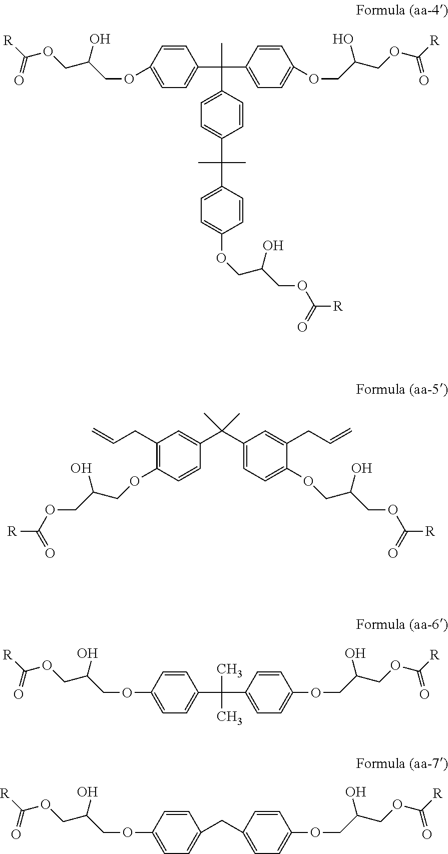

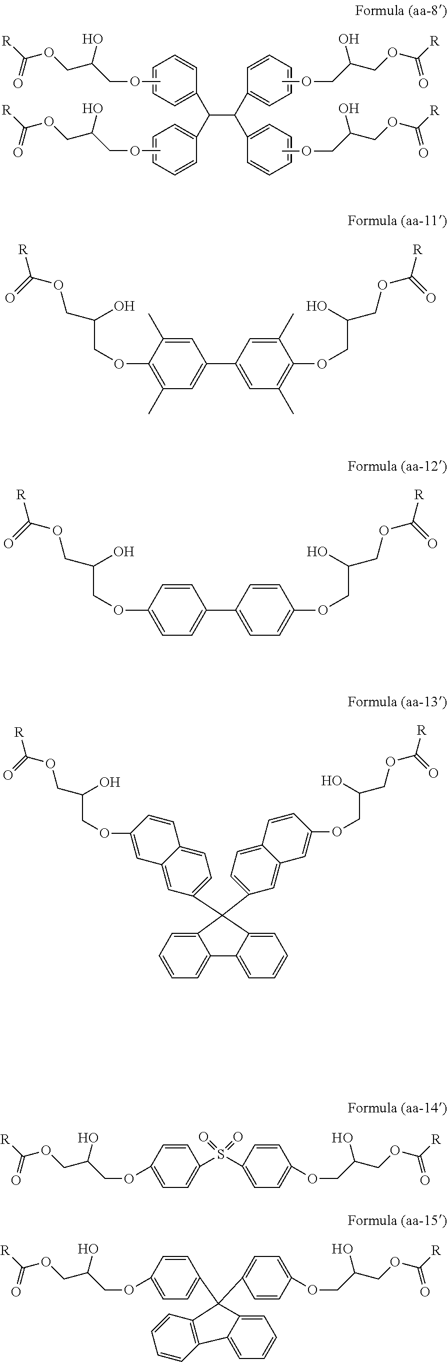

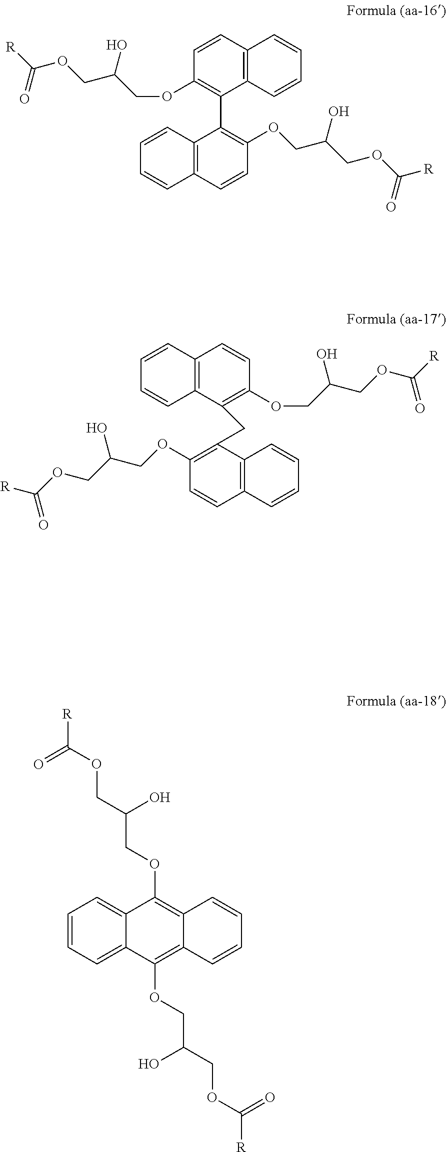

R in each of the aforementioned structural formulae is an aromatic ring or HCC-group derived from the aforementioned aromatic carboxylic acid, and at least one R is an HCC-group.

### [Crosslinking Agent]

The stepped substrate coating composition of the present invention may contain a crosslinking agent. The crosslinking agent is, for example, a melamine compound, a substituted urea compound, or a polymer thereof. The crosslinking agent is preferably a crosslinking agent having at least two crosslinkable substituents, for example, a compound such as methoxymethylated glycoluril (e.g., tetramethoxymethyl glycoluril), butoxymethylated glycoluril, methoxymethylated melamine, butoxymethylated melamine, methoxymethylated benzoguanamine, butoxymethylated benzoguanamine, methoxymethylated urea, butoxymethylated urea, or methoxymethylated thiourea. A condensate of such a compound may also be used.

The aforementioned crosslinking agent may be a crosslinking agent having high thermal resistance. The crosslinking agent having high thermal resistance is preferably a compound containing a crosslinkable substituent having an aromatic ring (e.g., a benzene ring or a naphthalene ring) in the molecule.

Examples of the compound include a compound having a partial structure of the following Formula (4) and a polymer or oligomer having a repeating unit of the following Formula (5).

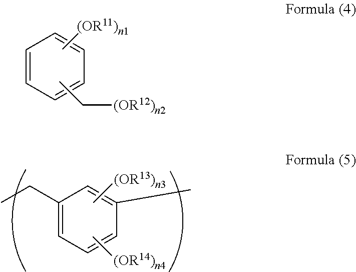

In the aforementioned Formulae, R¹¹, R¹², R¹³, and R¹⁴ are each a hydrogen atom or a C₁₋₁₀ alkyl group, and these alkyl groups may be the same as those exemplified above.

Examples of the compound of Formula (4) and the polymer or oligomer of Formula (5) are as follows.

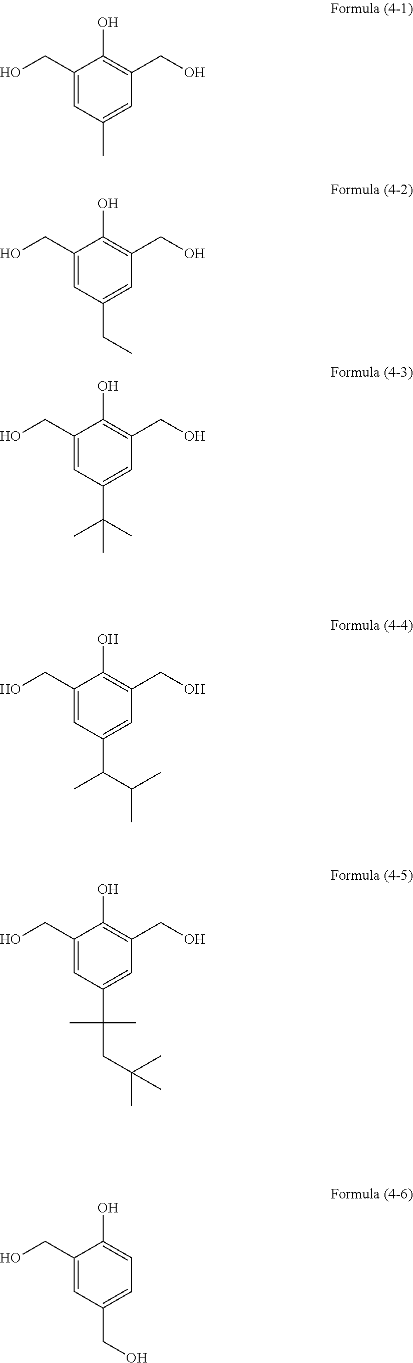

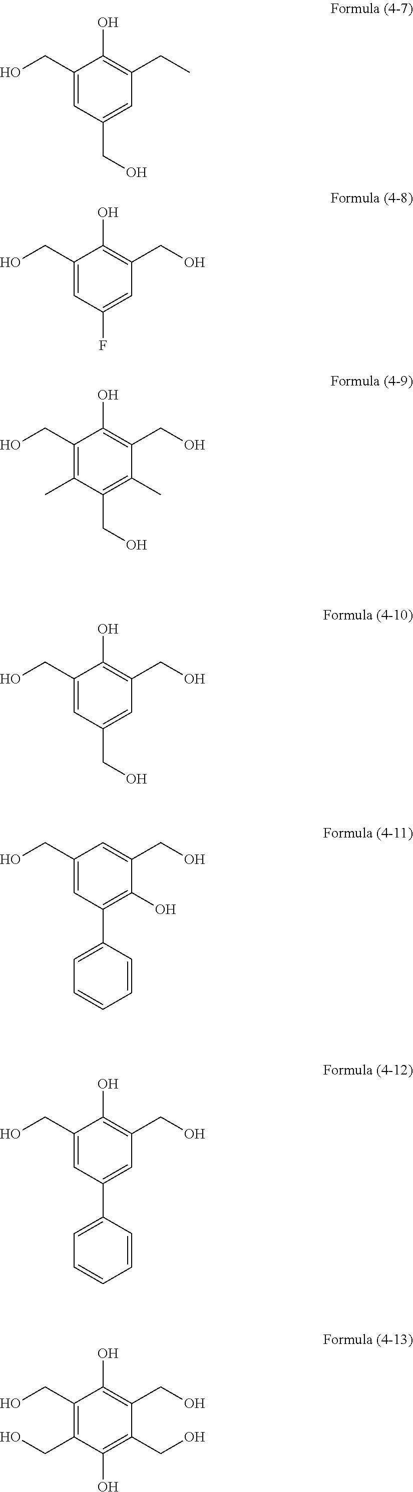

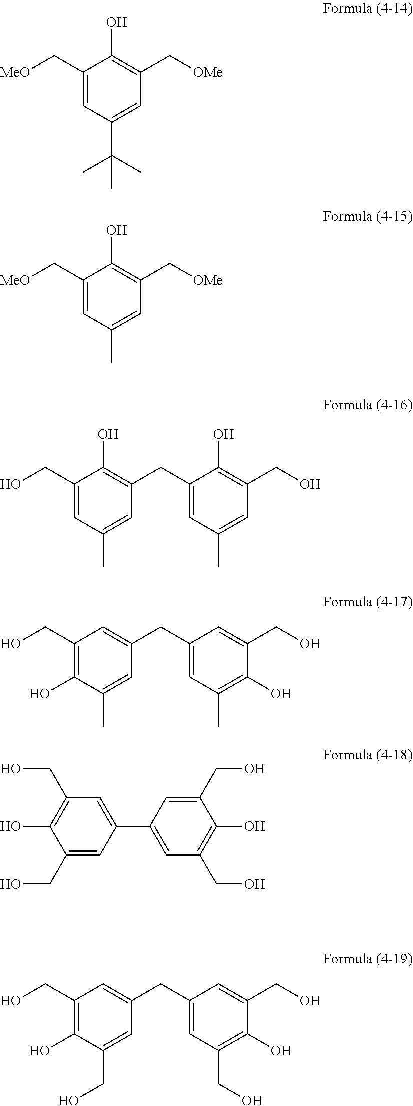

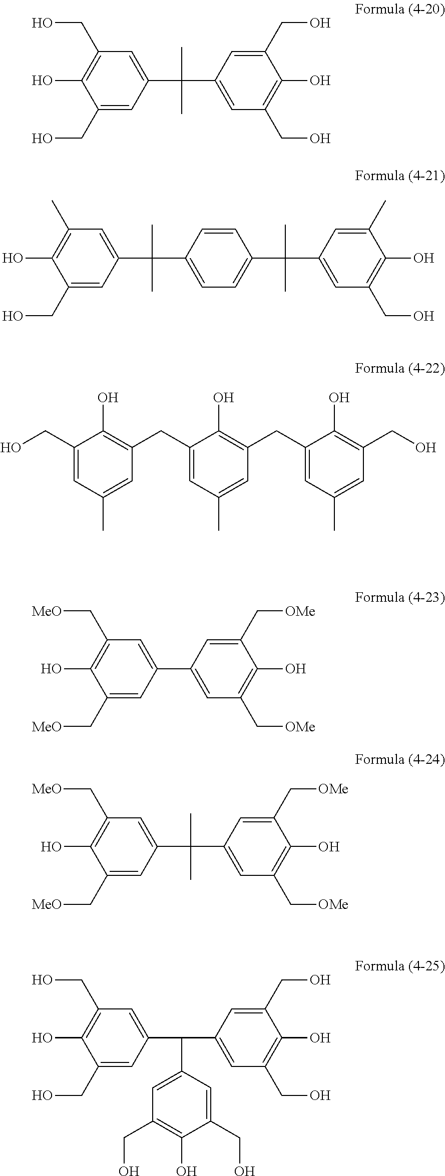 [SMILES: CC(C)(c1cc(CO)c(O)c(CO)c1)c1cc(CO)c(O)c(CO)c1 ; Cc1cc(C(C)(C)c2ccc(C(C)(C)c3cc(C)c(O)c(CO)c3)cc2)cc(CO)c1O ; Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O]

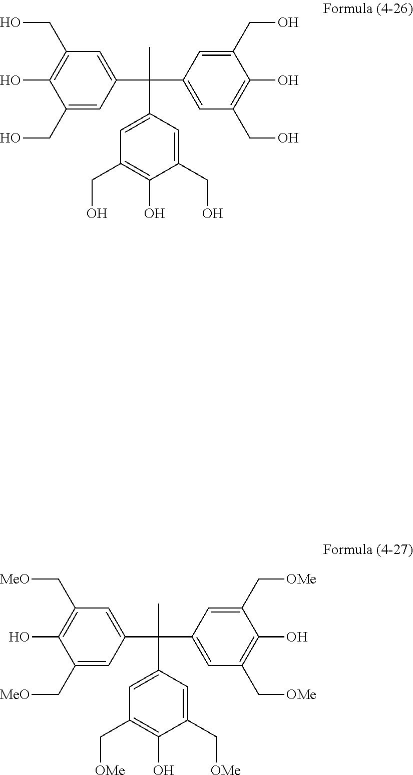 [SMILES: CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The aforementioned compounds can be obtained as products available from ASAHI YUKIZAI CORPORATION and Honshu Chemical Industry Co., Ltd. For example, among the aforementioned crosslinking agents, the compound of Formula (4-23) can be obtained as trade name TMOM-BP available from Honshu Chemical Industry Co., Ltd., and the compound of Formula (4-24) can be obtained as trade name TM-BIP-A available from ASAHI YUKIZAI CORPORATION.

The amount of the crosslinking agent added may vary depending on, for example, the type of a coating solvent used, the type of an underlying substrate used, the viscosity of a solution required, or the shape of a film required. The amount of the crosslinking agent is 0.001% by mass or more, 0.01% by mass or more, 0.05% by mass or more, 0.5% by mass or more, or 1.0% by mass or more, relative to the total solid content, and 80% by mass or less, 50% by mass or less, 40% by mass or less, 20% by mass or less, or 10% by mass or less, relative to the total solid content. Such a crosslinking agent may cause a crosslinking reaction by its self-condensation. When a crosslinkable substituent is present in any of the aforementioned polymers of the present invention, such a crosslinking agent may cause a crosslinking reaction with the crosslinkable substituent.

### [Solvent]

Examples of the solvent that can be used for dissolving the compound (A) in the present invention include ethylene glycol monomethyl ether, ethylene glycol monoethyl ether, ethylene glycol monobutyl ether, ethylene glycol monoisopropyl ether, ethylene glycol methyl ether acetate, ethylene glycol ethyl ether acetate, methyl cellosolve acetate, ethyl cellosolve acetate, diethylene glycol, diethylene glycol monomethyl ether, diethylene glycol monoethyl ether, diethylene glycol dimethyl ether, diethylene glycol diethyl ether, diethylene glycol monoethyl ether acetate, propylene glycol, propylene glycol monomethyl ether, propylene glycol monobutyl ether, propylene glycol monomethyl ether acetate, propylene glycol monoethyl ether, propylene glycol monoethyl ether acetate, propylene glycol propyl ether acetate, dipropylene glycol monomethyl ether, dipropylene glycol monoethyl ether, triethylene glycol dimethyl ether, toluene, xylene, styrene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 1-octanol, ethylene glycol, hexylene glycol, trimethylene glycol, 1-methoxy-2-buthanol, cyclohexanol, diacetone alcohol, furfuryl alcohol, tetrahydrofurfuryl alcohol, propylene glycol, benzyl alcohol, 1,3-butanediol, 1,4-butanediol, 2,3-butanediol, γ-butyrolactone, acetone, methyl isopropyl ketone, diethyl ketone, methyl isobutyl ketone, methyl normal butyl ketone, isopropyl acetate ketone, normal propyl acetate, isobutyl acetate, methanol, ethanol, isopropanol, tert-butanol, allyl alcohol, normal propanol, 2-methyl-2-butanol, isobutanol, normal butanol, 2-methyl-1-butanol, 1-pentanol, 2-methyl-1-pentanol, 2-ethylhexanol, isopropyl ether, 1,4-dioxane, N,N-dimethylformamide, N,N-dimethylacetamide, N-methylpyrrolidone, 1,3-dimethyl-2-imidazolidinone, dimethyl sulfoxide, and N-cyclohexyl-2-pyrrolidinone. These organic solvents may be used alone or in combination of two or more species.

[Acid and/or Acid Generator]

The stepped substrate coating composition of the present invention may contain an acid and/or an acid generator.

Examples of the acid include p-toluenesulfonic acid, trifluoromethanesulfonic acid, pyridinium p-toluenesulfonate, pyridinium phenolsulfonate, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

These acids may be used alone or in combination of two or more species. The amount of the acid is generally 0.0001 to 20% by mass, preferably 0.0005 to 10% by mass, more preferably 0.01 to 5% by mass, relative to the total solid content.

The acid generator may be, for example, a thermal acid generator.

Examples of the thermal acid generator include 2,4,4,6-tetrabromocyclohexadienone, benzoin tosylate, 2-nitrobenzyl tosylate, K-PURE [registered trademark] CXC-1612, CXC-1614, TAG-2172, TAG-2179, TAG-2678, TAG2689, and TAG2700 (available from King Industries Inc.), SI-45, SI-60, SI-80, SI-100, SI-110, and SI-150 (available from SANSHIN CHEMICAL INDUSTRY CO., LTD.), and other organic sulfonic acid alkyl esters.

These acid generators may be used alone or in combination of two or more species.

When an acid generator is used, the amount thereof is 0.01 to 10 parts by mass, or 0.1 to 8 parts by mass, or 0.5 to 5 parts by mass, relative to 100 parts by mass of the solid content of the resist underlayer film-forming composition.

### [Surfactant]

The stepped substrate coating composition of the present invention may contain a surfactant. Examples of the surfactant include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenyl ether and polyoxyethylene nonylphenyl ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as EFTOP [registered trademark] EF301, EF303, and EF352 (available from Mitsubishi Materials Electronic Chemicals Co., Ltd.), MEGAFAC [registered trademark] F171, F173, R30, R-30N, R-40, and R-40 LM (available from DIC Corporation), Fluorad FC430 and FC431 (available from Sumitomo 3M Limited), Asahi Guard [registered trademark] AG710, and SURFLON [registered trademark] S-382, SC101, SC102, SC103, SC104, SC105, and SC106 (available from Asahi Glass Co., Ltd.); and Organosiloxane Polymer KP341 (available from Shin-Etsu Chemical Co., Ltd.). A single species selected from these surfactants may be added, or two or more species of these surfactants may be added in combination.

The amount of the aforementioned surfactant is, for example, 0.01% by mass to 5% by mass, or 0.01% by mass to 2% by mass, or 0.01% by mass to 0.2% by mass, or 0.01% by mass to 0.1% by mass, or 0.01% by mass to 0.09% by mass, relative to the solid content (except for the solvent described below) of the stepped substrate coating composition of the present invention.

### [Production Method for Coated Substrate and Semiconductor Device]

Next will be described a method for forming a planarization film from the stepped substrate coating composition of the present invention. Specifically, the stepped substrate coating composition is applied onto a substrate used for the production of a precise integrated circuit element (e.g., a transparent substrate, such as a silicon/silicon dioxide coating, a glass substrate, or an ITO substrate) by an appropriate coating method using, for example, a spinner or a coater. Thereafter, the composition is baked (heated) to thereby form a coating film. Thus, a coated substrate is produced by a method including a step (i) of applying the stepped substrate coating composition to a stepped substrate, and a step (ii) of heating the composition applied in the step (i).

When a spinner is used for application of the composition, the application can be performed at a spinner rotation speed of 100 to 5,000 for 10 to 180 seconds.

The aforementioned substrate may have an open area (non-patterned area) and a patterned area of DENSE (dense) and ISO (coarse), and the pattern may have an aspect ratio of 0.1 to 10 or 0.1 to 100.

The “non-patterned area” refers to an area where a pattern (e.g., a hole or a trench structure) is absent on the substrate. “DENSE (dense)” refers to an area where patterns are densely present on the substrate, and “ISO (coarse)” refers to an area where interpattern distance is large and patterns are scattered on the substrate. The aspect ratio of a pattern is the ratio of the depth of the pattern to the width of the pattern. The pattern depth is generally several hundreds of nm (e.g., about 100 to 300 nm). DENSE (dense) is an area where patterns of about several tens of nm (e.g., 30 to 80 nm) are densely present at intervals of about 100 nm. ISO (coarse) is an area where patterns of several hundreds of nm (e.g., about 200 to 1,000 nm) are scattered.

The stepped substrate coating film (planarization film) preferably has a thickness of 0.01 μm to 3.0 μm.

In the step (ii), the heating is preferably performed at a temperature of 100°C to 500°C or 200°C to 400°C An acid is generated and curing reaction occurs at a temperature falling within such a range, to thereby achieve solvent resistance.

In the thus-formed stepped substrate coating film (planarization film), the Bias (difference in coating level) is preferably zero between the open area and the patterned area. The planarization can be performed so that the Bias falls within a range of 1 nm to 50 nm or 1 nm to 25 nm. The Bias between the open area and the DENSE area is about 15 nm to 20 nm, and the Bias between the open area and the ISO area is about 1 nm to 10 nm.

The stepped substrate coating film (planarization film) produced by the method of the present invention can be coated with a resist film, and the resist film can be exposed to light and developed by lithography, to thereby form a resist pattern. The substrate can be processed with the resist pattern. In this case, the stepped substrate coating film (planarization film) is a resist underlayer film, and the stepped substrate coating composition is a resist underlayer film-forming composition.

A resist can be applied onto the resist underlayer film, and the resist can be irradiated with light or electron beams through a predetermined mask, followed by development, rinsing, and drying, to thereby form a favorable resist pattern. If necessary, post exposure bake (PEB) may be performed during or after the irradiation with light or electron beams. The resist underlayer film at a portion where the resist film has been developed and removed in the aforementioned step can be removed by dry etching, to thereby form a desired pattern on the substrate.

The resist used in the present invention is a photoresist or an electron beam resist.

In the present invention, the photoresist applied onto the resist underlayer film for lithography may be either of negative and positive photoresists. Examples of the photoresist include a positive photoresist formed of a novolac resin and a 1,2-naphthoquinone diazide sulfonic acid ester; a chemically amplified photoresist formed of a binder having a group that decomposes with an acid to thereby increase an alkali dissolution rate and a photoacid generator; a chemically amplified photoresist formed of an alkali-soluble binder, a low-molecular-weight compound that decomposes with an acid to thereby increase the alkali dissolution rate of the photoresist, and a photoacid generator; a chemically amplified photoresist formed of a binder having a group that decomposes with an acid to thereby increase an alkali dissolution rate, a low-molecular-weight compound that decomposes with an acid to thereby increase the alkali dissolution rate of the photoresist, and a photoacid generator; and a photoresist having an Si atom-containing skeleton. Specific examples of the photoresist include trade name APEX-E available from Rohm and Haas Company.

In the present invention, the electron beam resist applied onto the resist underlayer film for lithography is, for example, a composition containing a resin having an Si—Si bond in a main chain and an aromatic ring at a terminal, and an acid generator that generates an acid through irradiation with electron beams; or a composition containing poly(p-hydroxystyrene) wherein a hydroxyl group is substituted with an N-carboxyamine-containing organic group, and an acid generator that generates an acid through irradiation with electron beams. In the latter electron beam resist composition, an acid generated from the acid generator through irradiation with electron beams reacts with an N-carboxyaminoxy group at a side chain of the polymer, and the polymer side chain decomposes into a hydroxyl group, exhibits alkali solubility, and dissolves in an alkaline developer, to thereby form a resist pattern. Examples of the acid generator that generates an acid through irradiation with electron beams include halogenated organic compounds, such as 1,1-bis [p-chlorophenyl]-2,2,2-trichloroethane, 1,1-bis [p-methoxyphenyl]-2,2,2-trichloroethane, 1,1-bis [p-chlorophenyl]-2,2-dichloroethane, and 2-chloro-6-(trichloromethyl)pyridine; onium salts, such as triphenylsulfonium salts and diphenyliodonium salts; and sulfonic acid esters, such as nitrobenzyl tosylate and dinitrobenzyl tosylate.

The exposure light used for the aforementioned photoresist is actinic rays, such as near-ultraviolet rays, far-ultraviolet rays, or extreme-ultraviolet rays (e.g., EUV, wavelength: 13.5 nm); for example, light having a wavelength of 248 nm (KrF laser beam), 193 nm (ArF laser beam), or 172 nm. No particular limitation is imposed on the usable photoirradiation method, so long as the method can generate an acid from a photoacid generator in the resist film. The dose of the exposure light is 1 to 5,000 mJ/cm², or 10 to 5,000 mJ/cm², or 10 to 1,000 mJ/cm².

The electron beam resist can be irradiated with electron beams by using, for example, an electron beam irradiation apparatus.

Examples of the developer for the resist film having the resist underlayer film formed from the stepped substrate coating composition of the present invention include aqueous solutions of alkalis, for example, inorganic alkalis, such as sodium hydroxide, potassium hydroxide, sodium carbonate, sodium silicate, sodium metasilicate, and aqueous ammonia, primary amines, such as ethylamine and n-propylamine, secondary amines, such as diethylamine and di-n-butylamine, tertiary amines, such as triethylamine and methyldiethylamine, alcoholamines, such as dimethylethanolamine and triethanolamine, quaternary ammonium salts, such as tetramethylammonium hydroxide, tetraethylammonium hydroxide, and choline, and cyclic amines, such as pyrrole and piperidine. The developer to be used may be prepared by addition of an appropriate amount of an alcohol (e.g., isopropyl alcohol) or a surfactant (e.g., a nonionic surfactant) to any of the aforementioned aqueous alkali solutions. Among these developers, quaternary ammonium salts are preferred, and tetramethylammonium hydroxide and choline are more preferred.

An organic solvent may be used as the developer. Examples of the organic solvent include methyl acetate, butyl acetate, ethyl acetate, isopropyl acetate, amyl acetate, isoamyl acetate, ethyl methoxyacetate, ethyl ethoxyacetate, propylene glycol monomethyl ether, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Such a developer may further contain, for example, a surfactant. The development is performed under appropriately determined conditions; i.e., a temperature of 5 to 50°C and a time of 10 to 600 seconds.

In the present invention, a semiconductor device can be produced through a step of forming a resist underlayer film on a semiconductor substrate from the resist underlayer film-forming composition; a step of forming a resist film on the resist underlayer film; a step of irradiating the resist film with light or electron beams, and developing the resist film, to thereby form a resist pattern; a step of etching the resist underlayer film with the resist pattern; and a step of processing the semiconductor substrate with the patterned resist underlayer film.

In the future, the formation of a finer resist pattern will cause a problem in terms of resolution and a problem in that the resist pattern collapses after development, and a decrease in the thickness of a resist will be demanded. Thus, it is difficult to form a resist pattern having a thickness sufficient for processing of a substrate. This requires a process for imparting a mask function, during the substrate processing, not only to the resist pattern, but also to a resist underlayer film that is formed between the resist film and the semiconductor substrate to be processed. The resist underlayer film required for such a process is not a conventional resist underlayer film having a high etching rate, but a resist underlayer film for lithography having a selection ratio of dry etching rate similar to that of the resist film, a resist underlayer film for lithography having a smaller selection ratio of dry etching rate than the resist film, or a resist underlayer film for lithography having a smaller selection ratio of dry etching rate than the semiconductor substrate. Such a resist underlayer film may be provided with an anti-reflective performance; i.e., the film may also have the function of a conventional anti-reflective coating.

Meanwhile, a finer resist pattern has started to be formed by using a process for making a resist pattern and a resist underlayer film thinner than the pattern width during the resist development by dry etching of the resist underlayer film. The resist underlayer film required for such a process is not a conventional anti-reflective coating having a high etching rate, but a resist underlayer film having a selection ratio of dry etching rate similar to that of the resist film. Such a resist underlayer film may be provided with an anti-reflective performance; i.e., the film may also have the function of a conventional anti-reflective coating.

In the present invention, after formation of the resist underlayer film of the present invention on a substrate, a resist may be applied directly to the resist underlayer film, or if necessary, the resist may be applied after formation of one to several layers of coating material on the resist underlayer film. This process reduces the pattern width of the resist film. Thus, even when the resist film is thinly applied for prevention of pattern collapse, the substrate can be processed with an appropriately selected etching gas.

Specifically, a semiconductor device can be produced through a step of forming a resist underlayer film on a semiconductor substrate from the resist underlayer film-forming composition; a step of forming, on the resist underlayer film, a hard mask from a coating material containing, for example, a silicon component or a hard mask (e.g., from silicon nitride oxide) by vapor deposition; a step of forming a resist film on the hard mask; a step of forming a resist pattern by irradiation of the resist film with light or electron beams and development; a step of etching the hard mask with the resist pattern by using a halogen-containing gas; a step of etching the resist underlayer film with the patterned hard mask by using an oxygen-containing gas or a hydrogen-containing gas; and a step of processing the semiconductor substrate with the patterned resist underlayer film by using a halogen-containing gas.

In consideration of the effect of the film formed from the stepped substrate coating composition of the present invention as an anti-reflective coating, since the light-absorbing moiety is incorporated into the skeleton of the film, the film does not diffuse any substance in the photoresist during heating and drying. The resist underlayer film exhibits high anti-reflective effect, since the light-absorbing moiety has sufficiently high light absorption performance.

The stepped substrate coating composition of the present invention has high thermal stability, and thus can prevent contamination of an upper-layer film caused by a decomposed substance during baking. Also, the composition can provide a temperature margin in a baking step.

Depending on process conditions, the film formed from the stepped substrate coating composition of the present invention can be used as a film having the function of preventing light reflection and the function of preventing the interaction between the substrate and the photoresist or preventing the adverse effect, on the substrate, of a material used for the photoresist or a substance generated during the exposure of the photoresist to light.

### EXAMPLES

### Synthesis Example 1

### Proportions of Materials Added: HP4700/9AC/PA=100/50/50

A 100-mL two-necked flask was charged with 4.127 g of 9-anthracenecarboxylic acid (available from Tokyo Chemical Industry Co., Ltd.) (hereinafter abbreviated as “9AC”), 6.00 g of HP-4700 (available from DIC Corporation), 0.345 g of ethyltriphenylphosphonium bromide (available from HOKKO CHEMICAL INDUSTRY CO., LTD.), and 28.736 g of propylene glycol monomethyl ether. Subsequently, the resultant mixture was heated to 140°C, and the mixture was stirred under reflux in a nitrogen atmosphere for about 24 hours. Thereafter, the mixture was cooled to room temperature, and 1.951 g of propiolic acid (available from Tokyo Chemical Industry Co., Ltd.) (hereinafter abbreviated as “PA”) was added to the mixture, followed by stirring under reflux in a nitrogen atmosphere at 60°C for about 36 hours. After completion of the reaction, 12.315 g of an anion-exchange resin (product name: DOWEX [registered trademark] 550A, available from MUROMACHI TECHNOS CO., LTD.) and 12.315 g of a cation-exchange resin (product name: Amberlite [registered trademark] 15JWET, available from ORGANO CORPORATION) were added to the resultant solution, and the mixture was subjected to ion-exchange treatment at room temperature for four hours. The ion-exchange resins were then separated to thereby prepare a solution of compound of Formula (1-1). The compound was found to have a weight average molecular weight Mw of 1,570 as determined by GPC in terms of polystyrene.

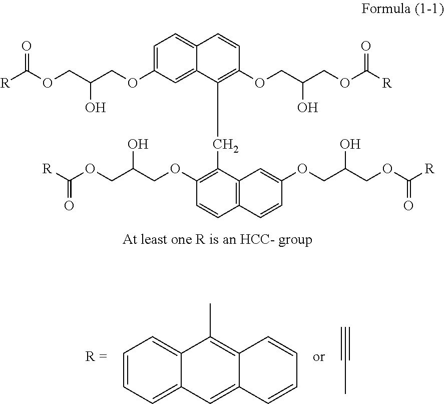

### Synthesis Example 2

### Proportions of Materials Added: HP4770/9AC/PA=100/50/50

A 100-mL two-necked flask was charged with 4.356 g of 9-anthracenecarboxylic acid (available from Tokyo Chemical Industry Co., Ltd.), 8.00 g of HP-4770 (available from DIC Corporation), 0.364 g of ethyltriphenylphosphonium bromide (available from HOKKO CHEMICAL INDUSTRY CO., LTD.), and 34.485 g of propylene glycol monomethyl ether acetate. Subsequently, the resultant mixture was heated to 140°C, and the mixture was stirred under reflux in a nitrogen atmosphere for about 24 hours. Thereafter, the mixture was cooled to room temperature, and 2.059 g of propiolic acid (available from Tokyo Chemical Industry Co., Ltd.) was added to the mixture, followed by stirring under reflux in a nitrogen atmosphere at 60°C for about 36 hours. After completion of the reaction, 14.779 g of an anion-exchange resin (product name: DOWEX [registered trademark] 550A, available from MUROMACHI TECHNOS CO., LTD.) and 14.779 g of a cation-exchange resin (product name: Amberlite [registered trademark] 15JWET, available from ORGANO CORPORATION) were added to the resultant solution, and the mixture was subjected to ion-exchange treatment at room temperature for four hours. The ion-exchange resins were then separated to thereby prepare a solution of compound of Formula (1-2). The compound was found to have a weight average molecular weight Mw of 2,620 as determined by GPC in terms of polystyrene.

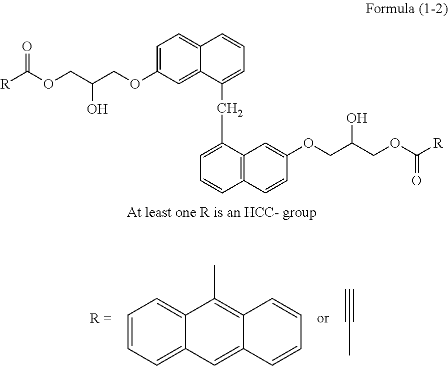

### Synthesis Example 3

### Proportions of Materials Added: NC7300/9AC/PA=100/50/50

A 100-mL two-necked flask was charged with 4.154 g of 9-anthracenecarboxylic acid (available from Tokyo Chemical Industry Co., Ltd.), 8.00 g of NC7300 (available from Nippon Kayaku Co., Ltd.), 0.347 g of ethyltriphenylphosphonium bromide (available from HOKKO CHEMICAL INDUSTRY CO., LTD.), and 21.697 g of propylene glycol monomethyl ether acetate. Subsequently, the resultant mixture was heated to 140°C, and the mixture was stirred under reflux in a nitrogen atmosphere for about 24 hours. Thereafter, the mixture was cooled to room temperature, and 1.964 g of propiolic acid (available from Tokyo Chemical Industry Co., Ltd.) was added to the mixture, followed by stirring under reflux in a nitrogen atmosphere at 60°C for about 36 hours. After completion of the reaction, 14.465 g of an anion-exchange resin (product name: DOWEX [registered trademark] 550A, available from MUROMACHI TECHNOS CO., LTD.) and 14.465 g of a cation-exchange resin (product name: Amberlite [registered trademark] 15JWET, available from ORGANO CORPORATION) were added to the resultant solution, and the mixture was subjected to ion-exchange treatment at room temperature for four hours. The ion-exchange resins were then separated to thereby prepare a solution of compound of Formula (1-3). The compound was found to have a weight average molecular weight Mw of 750 as determined by GPC in terms of polystyrene.

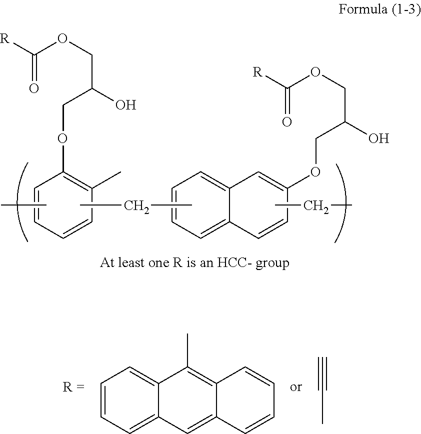

### Synthesis Example 4

In a two-necked flask, 40.0 g of trade name EHPE3150 (available from Daicel Corporation), 20.3 g of 9-anthracenecarboxylic acid, and 13.7 g of benzoic acid were dissolved in 302.0 g of propylene glycol monomethyl ether. Thereafter, 1.5 g of benzyltriethylammonium was added to the solution, and the mixture was refluxed for 24 hours, to thereby allow reaction to proceed. To the resultant solution were added 11 g of an anion-exchange resin (product name: DOWEX [registered trademark] 550A, available from MUROMACHI TECHNOS CO., LTD.) and 11 g of a cation-exchange resin (product name: Amberlite [registered trademark] 15JWET, available from ORGANO CORPORATION), and the mixture was subjected to ion-exchange treatment at room temperature for four hours. The ion-exchange resins were then separated to thereby prepare a solution of compound of Formula (1-4). The compound was found to have a weight average molecular weight Mw of 4,100 as determined by GPC in terms of polystyrene.

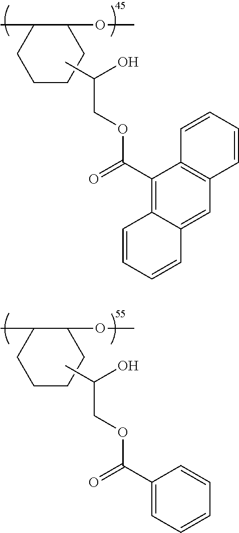

### Example 1

Firstly, 3.390 g of the resin solution prepared in Synthesis Example 1 (solid content: 24.42%) was mixed with 0.497 g of propylene glycol monomethyl ether containing 5% TAG2689 (thermal acid generator, available from King Industries Inc.), 0.166 g of TMOM-BP (crosslinking agent, available from Honshu Chemical Industry Co., Ltd.), 0.166 g of propylene glycol monomethyl ether acetate containing 1% surfactant (product name: MEGAFAC [trade name] R-40, fluorine-containing surfactant, available from DIC Corporation), 2.822 g of propylene glycol monomethyl ether, and 4.266 g of propylene glycol monomethyl ether acetate. Thereafter, the resultant mixture was filtered with a polytetrafluoroethylene-made microfilter (pore size: 0.1 μm), to thereby prepare a solution of a resist underlayer film-forming composition.

### Example 2

Firstly, 4.085 g of the resin solution prepared in Synthesis Example 2 (solid content: 20.27%) was mixed with 0.497 g of propylene glycol monomethyl ether containing 5% TAG2689 (thermal acid generator, available from King Industries Inc.), 0.166 g of TMOM-BP (crosslinking agent, available from Honshu Chemical Industry Co., Ltd.), 0.166 g of propylene glycol monomethyl ether acetate containing 1% surfactant (product name: MEGAFAC [trade name] R-40, fluorine-containing surfactant, available from DIC Corporation), 0.260 g of propylene glycol monomethyl ether, and 7.522 g of propylene glycol monomethyl ether acetate. Thereafter, the resultant mixture was filtered with a polytetrafluoroethylene-made microfilter (pore size: 0.1 μm), to thereby prepare a solution of a resist underlayer film-forming composition.

### Example 3

Firstly, 4.239 g of the resin solution prepared in Synthesis Example 3 (solid content: 19.53%) was mixed with 0.497 g of propylene glycol monomethyl ether containing 5% TAG2689 (thermal acid generator, available from King Industries Inc.), 0.1656 g of TMOM-BP (crosslinking agent, available from Honshu Chemical Industry Co., Ltd.), 0.166 g of propylene glycol monomethyl ether acetate containing 1% surfactant (product name: MEGAFAC [trade name] R-40, fluorine-containing surfactant, available from DIC Corporation), 2.822 g of propylene glycol monomethyl ether, and 4.111 g of propylene glycol monomethyl ether acetate. Thereafter, the resultant mixture was filtered with a polytetrafluoroethylene-made microfilter (pore size: 0.1 μm), to thereby prepare a solution of a resist underlayer film-forming composition.

### Comparative Example 1

Firstly, 5.212 g of the resin solution prepared in Synthesis Example 3 (solid content: 19.53%) was mixed with 0.204 g of propylene glycol monomethyl ether acetate containing product name: MEGAFAC [trade name] R-40 (fluorine-containing surfactant), 3.290 g of propylene glycol monomethyl ether, and 3.294 g of propylene glycol monomethyl ether acetate. Thereafter, the resultant mixture was filtered with a polytetrafluoroethylene-made microfilter (pore size: 0.1 μm), to thereby prepare a solution of a resist underlayer film-forming composition.

### Comparative Example 2

Firstly, 4.226 g of the resin solution prepared in Synthesis Example 4 (solid content: 23.24%) was mixed with 0.393 g of propylene glycol monomethyl ether containing 5% TAG2689 (thermal acid generator, available from King Industries Inc.), 0.196 g of TMOM-BP (crosslinking agent, available from Honshu Chemical Industry Co., Ltd.), 0.196 g of propylene glycol monomethyl ether acetate containing 1% surfactant (product name: MEGAFAC [trade name] R-40, fluorine-containing surfactant, available from DIC Corporation), 2.794 g of propylene glycol monomethyl ether, and 7.195 g of propylene glycol monomethyl ether acetate. Thereafter, the resultant mixture was filtered with a polytetrafluoroethylene-made microfilter (pore size: 0.1 μm), to thereby prepare a solution of a resist underlayer film-forming composition.

### (Solvent Resistance Test)

Each of the resist underlayer film compositions prepared in Example 3 and Comparative Example 1 was applied onto a silicon wafer with a spin coater. The silicon wafer was heated on a hot plate at 240°C for 60 seconds, to thereby form a resist underlayer film having a thickness of 200 nm. For evaluation of solvent resistance, the baked coating film was immersed in a solvent mixture of propylene glycol monomethyl ether and propylene glycol monomethyl ether acetate (7:3) for one minute, spin-dried, and then baked at 100°C for 60 seconds. The thickness of the resultant film was measured to thereby calculate film remaining rate (Table 1).

In Example 3, solvent resistance was achieved (film remaining rate: 100%) through curing by reaction with a crosslinking agent. In contrast, in Comparative Example 1, solvent resistance failed to be achieved due to insufficient curing only by heating.

TABLE 1

| | Film remaining rate |
|---|---|
| Example 3 | 100% |
| Comparative Example 1 | 6% |

### (Evaluation of Planarity and Fillability on Stepped Substrate)

For evaluation of planarity on a stepped substrate, the thicknesses of portions of a coating film were compared on an SiO₂ substrate having a thickness of 200 nm and having a dense patterned area (DENSE) (trench width: 50 nm, pitch: 100 nm) and a non-patterned open area (OPEN). Each of the resist underlayer film compositions prepared in Examples 1 to 3 and Comparative Example 2 was applied onto the aforementioned substrate with a spin coater, and then heated on a hot plate at 240°C for 60 seconds. The planarity of the stepped substrate was evaluated by observation with a scanning electron microscope (S-4800) available from Hitachi High-Technologies Corporation, and by measurement of the difference between the thickness of the substrate at the dense area (patterned area) and that at the open area (non-patterned area) (i.e., the difference in coating level between the dense area and the open area, which is called “Bias”). The term “planarity” as used herein refers to the case where a small difference is present between the thicknesses of portions of the coating film applied onto the patterned area (dense area) and the non-patterned area (open area); i.e., ISO-DENSE Bias is small (Table 2).

In Examples 1 to 3, the crosslinking initiation temperature of the crosslinkable group contained in the polymer can be increased, and thus sufficient reflow property is achieved, resulting in good planarity. In contrast, in Comparative Example 2, the crosslinking initiation temperature of the crosslinking agent is low, and thus sufficient reflow property fails to be achieved, resulting in poor planarity.

TABLE 2

| | | DENSE | OPEN | DENSE/OPEN |
|---|---|---|---|---|
| | | Thickness | Thickness | Difference in |
| | | (nm) | (nm) | coating level (nm) |
| Example 1 | 240 °C/60 s | 145 | 181 | 36 |
| Example 2 | 240 °C/60 s | 163 | 185 | 22 |
| Example 3 | 240 °C/60 s | 168 | 187 | 19 |
| Comparative | 240 °C/60 s | 157 | 210 | 53 |
| Example 2 | | | | |

### INDUSTRIAL APPLICABILITY

The stepped substrate coating composition of the present invention can fill a pattern sufficiently and thus can be used for forming a coating film having planarity on a substrate.

1. A coated substrate production method comprising
a step (i) of applying a stepped substrate coating composition to a stepped substrate, wherein the stepped substrate coating composition comprises a compound (A) serving as a main agent, a crosslinking agent, and a solvent, wherein the compound (A) has a partial structure of the following Formula (A-1): 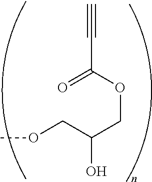
wherein the broken line is a bond to an aromatic ring; the aromatic ring is an aromatic ring forming a polymer skeleton or a monomer; and n is an integer of 1 to 4; and
a step (ii) of heating the composition applied in the step (i),
wherein the coated substrate production method does not include a photoirradiation step.

2. The coated substrate production method according to claim 1, wherein the composition is heated at a temperature of 100°C to 500°C in the step (ii).

3. The coated substrate production method according to claim 1, wherein the stepped substrate has an open area (non-patterned area) and a patterned area of DENSE (dense) and ISO (coarse), and the pattern has an aspect ratio of 0.1 to 100.

4. The coated substrate production method according to claim 1, wherein the stepped substrate has an open area (non-patterned area) and a patterned area of DENSE (dense) and ISO (coarse), and the difference in coating level (Bias) between the open area and the patterned area is 1 nm to 50 nm.

5. A semiconductor device production method comprising
a step of forming, on a stepped substrate, an underlayer film from a stepped substrate coating composition, wherein the stepped substrate coating composition comprises a compound (A) serving as a main agent, a crosslinking agent, and a solvent, wherein the compound (A) has a partial structure of the following Formula (A-1): 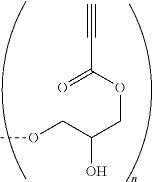
wherein the broken line is a bond to an aromatic ring; the aromatic ring is an aromatic ring forming a polymer skeleton or a monomer; and n is an integer of 1 to 4;
a step of forming a resist film on the underlayer film;
a step of irradiating the resist film with light or electron beams, or heating the resist film during or after irradiation with light or electron beams, and then developing the resist film, to thereby form a resist pattern;
a step of etching the underlayer film with the formed resist pattern; and
a step of processing the semiconductor substrate with the patterned underlayer film,
wherein the underlayer film forming step comprises the coated substrate production method according to claim 1.

6. The semiconductor device production method according to claim 5, wherein the composition is heated at a temperature of 100°C to 500°C in the step (ii).

7. The semiconductor device production method according to claim 5, wherein the stepped substrate has an open area (non-patterned area) and a patterned area of DENSE (dense) and ISO (coarse), and the pattern has an aspect ratio of 0.1 to 100.

8. The semiconductor device production method according to claim 5, wherein the stepped substrate has an open area (non-patterned area) and a patterned area of DENSE (dense) and ISO (coarse), and the underlayer film formed from the stepped substrate coating composition has a difference in coating level (Bias) between the open area and the patterned area of 1 nm to 50 nm.

9. A semiconductor device production method comprising
a step of forming, on a stepped substrate, an underlayer film from a stepped substrate coating composition, wherein the stepped substrate coating composition comprises a compound (A) serving as a main agent, a crosslinking agent, and a solvent, wherein the compound (A) has a partial structure of the following Formula (A-1): 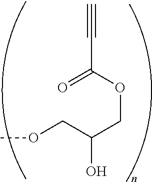
wherein the broken line is a bond to an aromatic ring; the aromatic ring is an aromatic ring forming a polymer skeleton or a monomer; and n is an integer of 1 to 4;
a step of forming a hard mask on the underlayer film;
a step of forming a resist film on the hard mask;
a step of irradiating the resist film with light or electron beams, or heating the resist film during or after irradiation with light or electron beams, and then developing the resist film, to thereby form a resist pattern;
a step of etching the hard mask with the formed resist pattern; a step of etching the underlayer film with the patterned hard mask; and
a step of processing the semiconductor substrate with the patterned underlayer film,
wherein the underlayer film forming step comprises the coated substrate production method according to claim 1.

10. The semiconductor device production method according to claim 9, wherein the composition is heated at a temperature of 100°C to 500°C in the step (ii).

11. The semiconductor device production method according to claim 9, wherein the stepped substrate has an open area (non-patterned area) and a patterned area of DENSE (dense) and ISO (coarse), and the pattern has an aspect ratio of 0.1 to 100.

12. The semiconductor device production method according to claim 9, wherein the stepped substrate has an open area (non-patterned area) and a patterned area of DENSE (dense) and ISO (coarse), and the underlayer film formed from the stepped substrate coating composition has a difference in coating level (Bias) between the open area and the patterned area of 1 nm to 50 nm.
